(19) United States
(12) Patent Application Publication
(10) Pub. No.: US 2008/0054337 A1
(43) Pub. Date: Mar. 6, 2008

(54) Flash Memory Device and Method for Manufacturing the Flash Memory Device

(76) Inventor: CHEOL SANG KWAK, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/848,610

(22) Filed: Aug. 31, 2007

(30) Foreign Application Priority Data
Aug. 31, 2006 (KR) 10-2006-0083804

(51) Int. Cl. H01L 29/788; H01L 21/336

(52) U.S. Cl. 257/316; 438/261; 257/E29.3; 257/E21.422

(57) ABSTRACT

Disclosed is a flash memory device comprising a semiconductor substrate in which a channel region is formed, an ONO (oxide-nitride-oxide) layer on the semiconductor substrate, a floating gate on the ONO layer, an anti-reflection layer on the floating gate; and a control gate on the anti-reflection layer. The channel region can be ion implanted before forming the floating gate.

The present application claims the benefit under 35 U.S.C. §119 of Korean Patent Application No. 10-2006-0083804, filed Aug. 31, 2006, which is hereby incorporated by reference in its entirety.

### BACKGROUND

Generally, semiconductor memory devices can be classified into volatile memories and nonvolatile memories. Most of the volatile memories are RAMs (random access memories), such as DRAMs (dynamic random access memories) and SRAMs (static random access memories), which enable data input and storage when power is supplied. However, if the power is cut off, data stored in the memory disappears and is gone.

On the other hand, most of the nonvolatile memories are ROMs (read only memories) and are characterized in the capability of storing data without requiring power to be supplied.

Nonvolatile memory devices include PROM (programmable ROM, EPROM (erasable PROM), and EEPROM (electrically erasable PROM).

According to an aspect of the process technologies, the nonvolatile memory devices may be classified as a floating gate series or a MIS (metal insulator semiconductor) series having at least two kinds of dielectric layers that are doubly or triply stacked therein.

The floating gate series memory device implements memory characteristics using potential wells. For example, an ETOX (EPROM tunnel oxide) structure is the most common floating gate series memory device applied to the current flash EEPROM.

The MIS series memory device performs memory characteristics using traps existing on a dielectric bulk, a dielectric-dielectric interface and a dielectric-semiconductor interface.

At the present time, MONOS (metal ONO semiconductor) and SONOS (silicon ONO semiconductor) structures are the most common MIS series memory devices applied to the flash EEPROM.

In the related flash memory devices, impurities of a source/drain region become diffused into a channel region to shorten channel length, so SCE (short channel effect) occurs. Thus, the characteristics of the flash memory devices may deteriorate.

### BRIEF SUMMARY

Embodiments of the present invention provide a method of manufacturing a flash memory device. According to embodiments, details are provided for a channel impurity ion implantation process to improve the operation characteristics of a flash memory device. Certain embodiments improve operation characteristics and reliability of a NOR flash memory device.

In an embodiment, there is provided a flash memory device comprising: a semiconductor substrate in which a channel region is formed; an ONO (oxide-nitride-oxide) layer on the semiconductor substrate; a floating gate on the ONO layer; an anti-reflection layer on the floating gate; and a control gate on the anti-reflection layer.

### BRIEF DESCRIPTION OF THE DRAWINGS

FIGS. 1 to 5 are cross-sectional views showing a method of manufacturing a flash memory device according to an embodiment of the present invention;

FIG. 6 is a graph showing experimental data results of an impurity ion implantation process of forming a channel region according to embodiments of the present invention;

FIG. 7 is a photograph after forming an anti-reflection layer and a by-product thereof on a floating gate; and

FIG. 8 is a photograph after both a floating gate and a control gate are formed.

### DETAILED DESCRIPTION

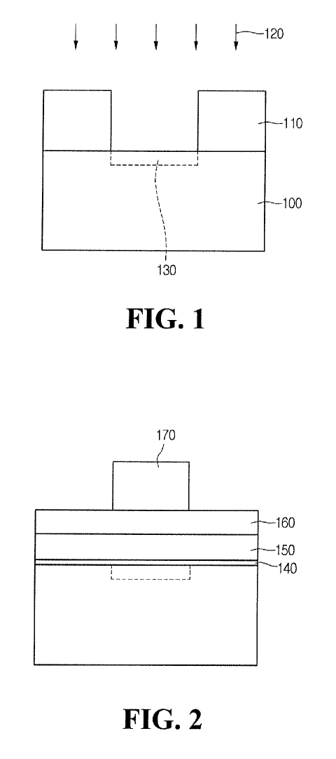

FIGS. 1 to 5 are cross-sectional views showing a method of manufacturing a flash memory device according to an embodiment of the present invention.

Referring to FIG. 1, a first photoresist 110 can be coated on a semiconductor substrate 100 except for the region in which a gate stack is to be formed, and an impurity ion implantation process can be performed using the first photoresist 110 as an ion implantation mask in order to form a channel region 130 in the semiconductor substrate 100.

In particular, the ion implantation process can be performed based on experimental data using various samples in order to improve device characteristics by inhibiting channel depletion of the flash memory device.

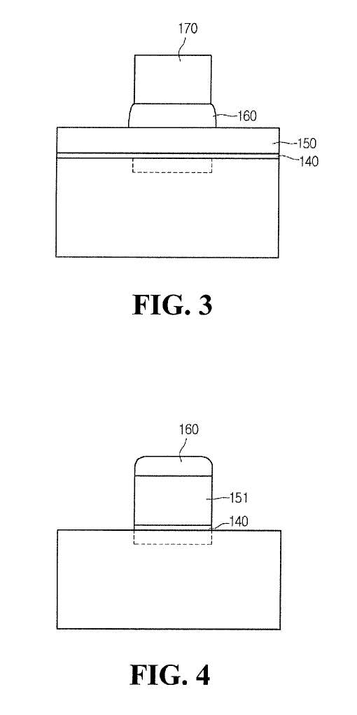

This will be described in detail below with reference to FIG. 6.

FIG. 6 is a graph showing experimental data results of an impurity ion implantation process of forming the channel region according to embodiments of the present invention.

That is, FIG. 6 shows breakdown simulation results according to impurity ion doping for forming the channel region. It should be noted that impurity ion doping dose for forming the channel region 130 should be at least 3.0×10¹³/cm² in order to obtain at least 5V representing a desired level of breakdown voltage in the device.

In an embodiment, boron ions are used as impurities for forming the channel region 130. The boron ions can be implanted with a dose of 3.0×10¹³/cm² to 4.0×10¹³/cm². Accordingly, the operation characteristics of a flash memory device manufactured through this ion implantation and subsequent processes can be improved.

Although not shown, an isolation layer is formed in the semiconductor substrate 100 in order to define an active region. In one embodiment, the isolation layer is formed through an STI (shallow trench isolation) process.

Referring to FIG. 2, after forming the channel region 130 in the semiconductor substrate 100, the first photoresist 110 is removed and then a process is performed to form a floating gate.

In an embodiment, after removing the first photoresist 110, an ONO (oxide-nitride-oxide) layer 140, a first polysilicon layer 150 and an anti-reflection layer 160 can be sequentially formed on the semiconductor substrate 100.

The ONO layer 140 can be formed by sequentially forming a first oxide layer, a nitride layer and a second oxide layer on the semiconductor substrate 100. In one embodiment, the ONO layer 140 can be selectively etched to remain on a portion of the substrate 100 above the upper portion of the channel region 130.

According to an embodiment the first oxide layer can have a thickness of 10 Å to 50 Å formed by a thermal oxidation process, the nitride layer can have a thickness of 50 Å to 160 Å formed by a CVD (chemical vapor deposition) process, and the second oxide layer can have a thickness of 10 Å to 80 Å formed by a CVD process.

After depositing the first polysilicon layer 150 on the ONO layer 140, the anti-reflection layer 160 having a predetermined thickness can be formed on the first polysilicon layer 150.

The anti-reflection layer 160 may include a single layer of Ti or TiN, or a multi-layer of Ti and TiN. In an embodiment incorporating a multi-layer of Ti and TiN, the Ti may have a thickness of 50 Å to 200 Å and the TiN may have a thickness of 200 Å to 500 Å.

After forming the anti-reflection layer 160, a second photoresist 170 can be formed on the anti-reflection layer 160 for forming a gate stack.

Referring to FIG. 3, the anti-reflection layer 160 can be etched using the second photoresist 170 as an etching mask. As a result of the etching, a by-product of the anti-reflection layer 160 remains with the anti-reflection layer 160 on the first polysilicon layer 150 as shown in the figure.

In particular, as the anti-reflection layer 160 is etched through the etching process, the by-product of the anti-reflection layer 160 partially remains on the sidewalls thereof. Thus, the anti-reflection layer 160 becomes wider than the pattern length of the second photoresist 170.

Referring to FIG. 4, after etching the anti-reflection layer 160, the first polysilicon layer 150 is etched to form a gate stack.

In detail, the first polysilicon layer 150 can be etched using the anti-reflection layer 160 as a mask, thereby forming a floating gate 151 under the anti-reflection layer 160. The ONO layer 140 can be etched to remain on the upper portion of the channel region 130 by a desired width.

Referring to FIG. 5, a second polysilicon layer can be formed on the floating gate 151, and can be etched to form a control gate 180.

Then, an oxide layer 190 can be deposited on the control gate 180 and etched to form oxide layer 190 that covers the gate stack including the control gate 180 and the floating gate 151.

In embodiments of the present invention, the process of forming an impurity region with an LDD structure including shallow impurity and deep impurity regions in the semiconductor substrate 100 can then be performed using a related art method so detailed description thereof will be omitted.

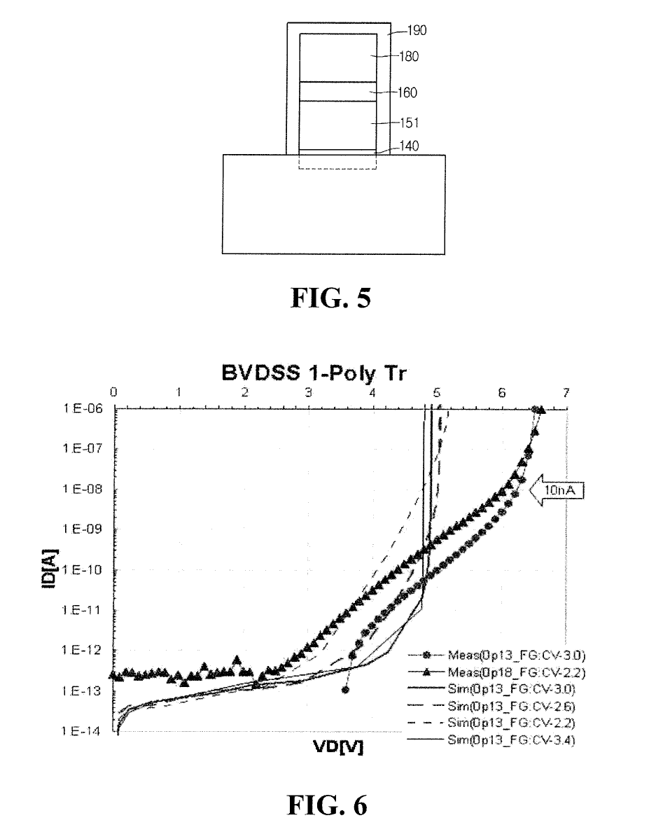

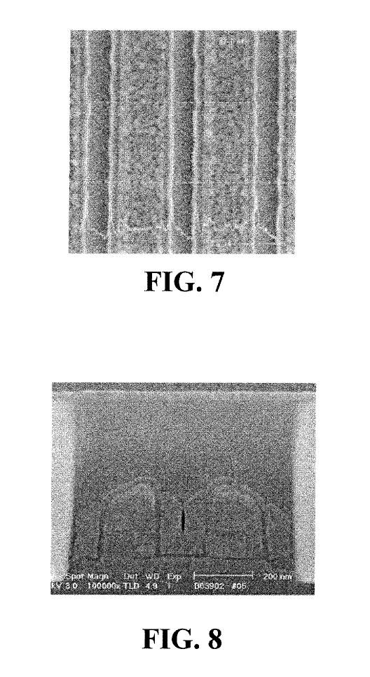

FIGS. 7 and 8 show SEM photographs of a flash memory device manufactured using the method as described above.

FIG. 7 is a plan view photograph after forming the anti-reflection layer and the by-product thereof on the floating gate according to an embodiment of the present invention, and FIG. 8 is a photograph after both the floating gate and the control gate are formed according to an embodiment of the present invention.

According to the embodiments as described above, details of a channel impurity ion implantation process are provided to improve the operation characteristics of a flash memory device. In addition, the operation performance of the flash memory device can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A flash memory device, comprising:
a semiconductor substrate comprising an ion implanted channel region;
an ONO (oxide-nitride-oxide) layer on the semiconductor substrate above the channel region;
a floating gate on the ONO layer;
an anti-reflection layer on the floating gate; and
a control gate on the anti-reflection layer.

2. The flash memory device according to claim 1, wherein the channel region is implanted with boron ions at a dose of 3.0×10¹³/cm² to 4.0×10¹³/cm².

3. The flash memory device according to claim 1, wherein the anti-reflection layer comprises a single layer of Ti or TiN or a multi-layer of Ti and TiN.

4. A method of manufacturing a flash memory device, comprising:
forming a photoresist pattern on a semiconductor substrate for forming a channel region;
implanting impurity ions into the semiconductor substrate using the photoresist pattern as an ion implantation mask to form the channel region;
forming an ONO (oxide-nitride-oxide) layer, a first polysilicon layer, and an anti-reflection layer on the semiconductor substrate having the channel region;
forming a gate stack by etching the anti-reflection layer and the first polysilicon layer; and
forming a second polysilicon layer on the first polysilicon layer.

5. The method according to claim 4, wherein implanting impurity ions into the semiconductor substrate comprises implanting boron ions at a dose of 3.0×10¹³/cm² to 4.0×10¹³/cm².

6. The method according to claim 4, wherein forming the gate stack by etching the anti-reflection layer and the first polysilicon layer comprises:
forming a second photoresist pattern on the anti-reflection layer;
etching the anti-reflection layer using the second photoresist pattern as an etch mask, whereby a by-product of the anti-reflection layer partially remains on sidewalls of the etched anti-reflection layer; and
etching the first polysilicon layer using the etched anti-reflection layer having a by-product remaining on its sidewalls as an etch mask.

7. The method according to claim 4, wherein the anti-reflection layer comprises a single layer of Ti or TiN or a multi-layer of Ti and TiN.
